(19) United States
(12) Patent Application Publication
(10) Pub. No.: US 2023/0410529 A1
(43) Pub. Date: Dec. 21, 2023

(54) Method and System for MonitoringTrees Endangering Power Lines

(71) Applicant: Robert Bosch GmbH, Stuttgart (DE)

(72) Inventor: Tomasz Bien, Ludwigsburg (DE)

(21) Appl. No.: 18/330,034

(22) Filed: Jun. 6, 2023

(30) Foreign Application Priority Data
Jun. 17, 2022 (DE) 10 2022 206 091.1

(51) Int. Cl. G06V 20/56; G06V 10/12; G06V 10/22; G06T 15/20; G06T 7/194; G06V 20/10

(52) U.S. Cl. CPC G06V 20/56; G06V 10/12; G06V 10/22; G06T 15/205; G06T 7/194; G06V 20/188; G06V 2201/07; G06T 2207/30188

(57) ABSTRACT

A method for monitoring trees endangering power lines using a vehicle network, which comprises a vehicle and a central computer, the vehicle including an image capturing sensor system, an image processing unit, and a locating system, and wirelessly connectable to the central computer in a data-conducting manner, and wherein the vehicle network covers a particular area and the vehicle can travel within the area, such that the trees endangering power lines within the area can be automatically monitored by the vehicle during a journey, includes capturing image information of an environment with the image capturing sensor system of a relevant vehicle during a journey, determining tree information with the image processing unit of the vehicle, taking into account power lines, based on the captured image information, and sending from the vehicle to the central computer the determined tree information and/or tree information evaluated by an evaluation unit of the vehicle.

This application claims priority under 35 U.S.C. § 119 to patent application no. 10 2022 206 091.1, filed on Jun. 17, 2022 in Germany, the disclosure of which is incorporated herein by reference in its entirety.

The present disclosure relates to a method for monitoring trees endangering power lines. In particular, the disclosure relates to a vehicle and a vehicle network for monitoring trees endangering power lines.

### BACKGROUND

The regional and supra-regional power supply with a power grid is a mega cap industry with a market size of approximately $30 billion globally and a growth rate of approximately 5% per year. The power lines of a power grid are regionally and nationally distributed and lead to end users (e.g., households). The higher the population density in a region, the higher the power line density in that region.

The supply reliability of the power grid is particularly important for industry and commerce. A power supply interruption can result in unavoidable damage. For example, in aluminum refineries, a power supply interruption can lead to destruction of the aluminum smelter.

Power suppliers make a huge effort to operate the power grids within the allowable limits of frequency, voltage, and line load. However, trees that are located near power lines can also represent a factor affecting supply reliability and must be monitored. This is because the branches and leaves of trees may come into contact with a power line during growth, such that the power line is interrupted, or the relevant power transmission or power distribution infrastructure is destroyed by a resulting short circuit. In fact, approximately 20% of unplanned power failures are caused by trees and other vegetation.

In order to solve the problem described above, the trees near power lines must be trimmed regularly. This is a tremendous task that occupies many people around the world. In the state of New Jersey in the United States alone, of the approximately 8.8 million inhabitants, approximately 230 people work to trim trees near power lines. Because the trimmed trees can grow again and consequently endanger the power lines again, there is a desire to monitor the trees.

Currently, power suppliers can estimate the tree trim dates based only on a very simple model. For example, it is believed that trimmed trees require five years of growth time before they again pose a hazard to the power lines. This process is insufficient and inaccurate for monitoring trees endangering power lines, while also resulting in tremendous inefficiencies and increased operating costs.

There is therefore a desire to specify a method for monitoring trees endangering power lines, by which the trees can be automatically and efficiently monitored.

### SUMMARY

This purpose is served by a method for monitoring trees endangering power lines using a vehicle network, which comprises a plurality of vehicles and a central computer, wherein at least one vehicle comprises an image capturing sensor system, an image processing unit, and a locating system and is wirelessly connectable to the central computer in a data-conducting manner, and wherein the vehicle network covers a particular area and each vehicle can travel within the area, such that the trees endangering power lines within the area can be automatically monitored by the at least one vehicle during a journey, comprising at least the following steps:
a) capturing image information of an environment with the image capturing sensor system of a relevant vehicle during a journey,
b) determining tree information with the image processing unit of the vehicle, taking into account power lines, based on the captured image information, and
c) sending from the vehicle to the central computer the determined tree information and/or tree information evaluated by an evaluation unit of the vehicle.

It is known that positioning and navigation of a vehicle for automated or autonomous driving can be accomplished with the aid of a highly precise locating system. A vehicle as such can also “see” its environment by way of an image capturing sensor system and can wirelessly communicate with a remote server by way of cloud computing for its steering. In addition, the computing power of computers is constantly increasing according to Moore's Law. In addition, it is known that the tree features such as tree trunk diameter and tree height can be captured visually using an image capturing device.

It is therefore conceivable that the sensors already configured in vehicles for automated or autonomous driving can also be used in order to automatically monitor trees endangering power lines.

Proceeding from the above, a new option for monitoring trees endangering power lines by using hardware already existing in vehicles is described. A vehicle network comprising a central computer and a plurality of vehicles is proposed for this purpose. The vehicle is preferably an automated or autonomous vehicle.

Preferably, each vehicle comprises at least one image capturing sensor system, such as a laser scanner or camera, and thus, according to step a), image information of an environment can be captured by the image capturing sensor system of a relevant vehicle during a journey. In an automated or autonomous vehicle, a laser scanner and/or camera is typically configured in order to detect obstacles and/or for map-based navigation. In any case, the laser scanner captures point clouds or the camera captures images around the environment while driving. The point clouds or images around the environment that are initially captured in order to detect obstacles or for map-based navigation can also be used directly in order to detect trees in the form of image information.

According to step b), tree information is determined, taking into account power lines, based on the image information captured in step a). In principle, this only requires an additional software adaptation, i.e., software for capturing tree features while taking into account power lines. With the software, the tree features can be extracted from the image information captured by the image capturing sensor system during a journey. The software can be stored in an image processing unit and executed by this image processing unit. It is possible to execute an on-board computer already configured in the vehicle as the image processing unit or to configure an additional image processing unit independently of the on-board computer in the vehicle.

Preferably, each vehicle comprises a locating system, such as a GNSS-based or a GNSS-based and INS-based locating system, for determining where the detected trees endangering the power lines are located.

In addition, each vehicle preferably wirelessly connects to the central computer in a data-conducting manner, such as via Wi-Fi and/or cellular network, so that, according to step c), the determined tree information and/or tree information evaluated by an evaluation unit of the vehicle can be sent by the vehicle to the central computer. It is possible to send the detected trees and their locations to the central computer in the form of binary data information.

As described above, the vehicle network is generally a distributed system using cloud computing. The central computer can be located anywhere, e.g., in a computer room of a service provider, who is authorized to obtain data from vehicles of the vehicle network via a wireless, data-conducting connection. Thus, during their journey over an area, the vehicles can inform the central computer about the trees “seen” with their image capturing sensor system.

In principle, with the proposed method, no additional hardware costs are required with respect to the vehicles. Rather, it is a matter of a software adaptation to the vehicles. As such, the vehicle network can be constantly expanded with an increasing number of vehicles into a large network over time. Thus, a vehicle network for automated monitoring of trees endangering power lines can be cost-effective and practical. As a result, the problems described in relation to the prior art can be alleviated or at least partially solved.

A power grid typically consists of a supra-regional transmission grid, as well as regional and local distribution grids. With the described method, in particular, the tree inventory for the regional and local distribution networks is monitored. The power lines here refer to medium and low voltage lines, in particular. The size of the area covered by the vehicle network will depend on the number of vehicles available and the coverage of the available radio network. For example, the trees outside the area covered by the vehicle network can be monitored with dedicated drone flights.

The disclosure uses a vehicle network with automated or autonomous vehicles for automatically monitoring the tree inventory near power lines. The monitoring is based on an image recognition and is performed using the sensors configured in the vehicles for autonomous driving, in particular high-resolution cameras and highly precise GNSS-based locating systems. In principle, this does not require any additional hardware construction in the vehicles, but only requires a software adjustment for the detection of tree information regarding power lines. Via a wireless connection between the vehicles and a central computer, the tree information captured by the vehicles during their journey can be sent to the central computer. The central computer can be located at a service provider. For example, the service provider can be an OEM (original equipment manufacturer) or another conceivable company that is authorized to obtain the tree information captured by the vehicles. After obtaining tree information from vehicles, the central computer can inform the power company or power supplier (as the customer of the service provider or the relevant department for power grid reliability) of the potential hazards.

With the method described, the vehicle network can provide a software-based and data-based service to the power company or power system distributor in order to assist in monitoring trees endangering power lines. By contrast to the known, inaccurate model assumption, this is an automatic and rule-based monitoring. The central computer can provide the relevant department with the tree-relevant information, so that it can be planned in a timely manner where and when to trim the trees in order to reduce monitoring costs, maintain a high supply reliability of the power system, and avoid overgrowth of the trees in the vicinity of power lines.

It is preferred when, prior to step c), location information regarding the tree information is captured by the locating system, and in step c) the captured location information is sent to the central computer.

In particular, the locating system means a GNSS-based locating system that comprises a GNSS receiver for capturing GNSS data. By means of the GNSS data, the location and/or the time can be determined. GNSS is the abbreviation for Global Navigation Satellite System (GPS, GLONASS, Galileo, and Beidou) for position determination and navigation on Earth and in the air by receiving navigation satellite signals (GNSS signals). The GNSS-based locating system is particularly advantageous for outdoor positioning and navigation.

This is because a sophisticated locating system, e.g., for autonomous driving, comprises a GNSS-based navigation component and image capturing sensor system for detecting obstacles, anyway. It is therefore also conceivable to integrate the image capturing sensor system technology and the image processing unit as well as the evaluation unit into the GNSS-based locating system. In this respect, the additional image processing unit as well as the evaluation unit relates essentially only to a software adaptation, which the computing unit of the locating system can also take over. Such an all-in-one locating system simplifies the construction of the vehicle network.

It is preferable that, between step b) and step c), the tree information is evaluated by an evaluation unit of the vehicle in order to detect trees endangering power lines, whose branches and leaves may come into contact with a power line during growth, and in step c) the evaluated tree information with the information of the detected trees is sent to the central computer. The relevant vehicle takes over the evaluation task in this case. The amount of data to be sent to the central computer can thus be significantly reduced. This is particularly advantageous for areas where the radio network is weak.

It is also preferred when, in step c), the determined tree information is sent to the central computer, and after step c) the central computer evaluates the tree information in order to detect trees endangering power lines, whose branches and leaves may come into contact with a power line during growth. The central computer takes over the evaluation task, and thus the computing power of the on-board computer on the vehicle can be reduced.

It is preferred when, in step a), the image information is captured by a laser scanner (e.g., LIDAR), a camera, and/or a 360° spherical camera.

A laser scanner, in particular a three-dimensional (3D) laser scanner, can generate high-accuracy and dense 3D point clouds and typically can be configured in a vehicle for detecting obstacles and/or for indoor navigation. Also, with a laser scanner, tree information can be captured, such as tree trunk diameter, tree height, leaf surface density, tree volume, biomass, and/or blade pitch angle during a journey of a laser scanner-equipped vehicle. In particular, the field of view of the laser scanner is greater when the capturing of the tree information is performed during a movement, such that the maximum measurement distance can be, for example, 100 meters. With the laser scanner, the tree information can be easily captured from large areas with numerous trees.

It is also possible to capture image information with a camera. In so doing, the camera can capture a plurality of two-dimensional (2D) images from which a three-dimensional (3D) image can be reconstructed during a journey of a camera-equipped vehicle. Based on the reconstructed 3D image, the tree information can be captured. Preferably, the camera is a 360° spherical camera capable of capturing images in all directions, whose field of vision is thus omnidirectional, such that tree information can be easily captured by large areas with numerous trees.

It is also preferred when, in step b), the tree information is determined by the following sub-steps:
1) reconstructing 3D image information from the captured image information based on the SFM approach,
2) determining the tree information based on the reconstructed 3D image information.
   Structure-from-Motion (SFM) is a method to obtain 3D information by overlapping 2D images with a time offset, taking advantage of the parallax. With the SFM approach, it is particularly advantageous to capture the tree information during a movement.

Furthermore, a vehicle is proposed, comprising,
an image capturing sensor system for capturing image information of an environment of the vehicle during a journey,
an image processing unit for determining tree information, taking into account power lines, based on image information, and
a locating system for capturing location information regarding tree information, wherein the vehicle is wirelessly connectable to a central computer in a data-conducting manner in order to send tree information and location information regarding this tree information to the central computer.

It is preferable when the vehicle comprises an evaluation unit for evaluating tree information in order to detect trees endangering power lines, whose branches and leaves may come into contact with a power line during growth.

To this end, it is conceivable to use a computer program to carry out a method as described herein. In other words, this aspect relatives in particular to a computer program (product) comprising commands that, when the program is executed by a computer, prompt the latter to perform a method described herein.

It is also conceivable to use a machine-readable storage medium, on which the computer program proposed herein is stored. Conventionally, the machine-readable storage medium is a computer-readable data carrier.

The storage medium with the stored computer program can be configured in the control unit of the respective locating systems and/or in the central computer.

Furthermore, a vehicle network is proposed for monitoring trees endangering power lines, comprising a central computer and a plurality of vehicles, wherein at least one vehicle comprises
an image capturing sensor system for capturing image information of an environment of the vehicle during a journey,
an image processing unit for determining tree information, taking into account power lines, based on image information,
a locating system for capturing location information regarding tree information, and is wirelessly connected to a central computer in a data-conducting manner in order to send tree information and location information regarding this tree information to the central computer.

The term “vehicle network” here substantially means a distributed system representing an association of independent computers (control devices of the locating systems and central computers) presenting themselves as service providers to the user (e.g., power supply companies) as a single system.

It is preferred when the at least one vehicle comprises an evaluation unit for evaluating tree information in order to detect trees endangering power lines, whose branches and leaves may come into contact with a power line during growth.

It is preferred when the central computer is configured so as to evaluate tree information in order to detect trees endangering power lines, whose branches and leaves may come into contact with a power line during growth.

### BRIEF DESCRIPTION OF THE DRAWINGS

The disclosure and the technical environment are explained in further detail below with reference to FIG. 1. It should be noted that FIG. 1 is schematic in nature. It should also be noted that the features shown in FIG. 1 do not necessarily have to be used in the presented combination; partial features can rather be extracted and combined with other explanations of the description. Something else will apply only if it is explicitly shown here as a mandatory combination of features.

FIG. 1 depicts a vehicle network for monitoring trees endangering power lines.

### DETAILED DESCRIPTION

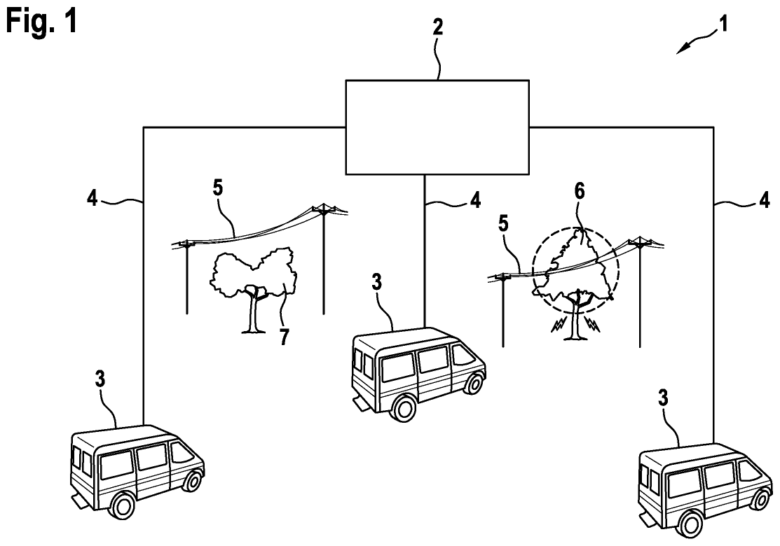

FIG. 1 schematically and by way of example illustrates a vehicle network 1 for monitoring trees 6 endangering power lines 5. The vehicle network 1 comprises a central computer 2 and a plurality of vehicles 3 (as an example, three vehicles 3 are shown here). The vehicles 3 can travel within the area covered by the vehicle network 1. The central computer 2 can be located in a computer room (not shown) of a service provider. Each vehicle 3 is connected to the central computer 2 by a wireless connection 4 in a data-conducting manner.

Each vehicle 3 comprises an image capturing sensor system (not shown) for “seeing” the environment while traveling, an image processing unit (not shown) for detecting trees 6, 7, taking into account power lines 5 from the “seen” environment, and a GNSS-based locating system (not shown) for determining where trees 6, 7 are located. Optionally, each vehicle 3 can comprise an evaluation unit (not shown) in order to evaluate whether the detected trees 6, 7 are trees 6 endangering power lines 5 or whether they are trees 7 not endangering power lines 5, so that only the trees 6 endangering power lines 5 with their location information can be transmitted to the central computer 2 through the wireless connection 4. Optionally, the central computer 2 can take over the evaluation task, so that the trees 6, 7 in the vicinity of the power lines 5 are to be transmitted to the central computer 2 with their location information.

With the disclosure, the vehicle network 1 can provide a software-based and data-based service to the power company or power system distributor in order to assist in monitoring trees 6 endangering power lines 5. By contrast to the known, inaccurate model assumption, this is an automatic and rule-based monitoring. The central computer 2 can provide the relevant department of the power supplier with the tree-relevant information, so that it can be planned in a timely manner where and when to trim the trees 6 in order to reduce monitoring costs, maintain a high supply reliability of the power system, and avoid overgrowth of the trees 6, 7 in the vicinity of power lines 5.

What is claimed is:

1. A method for monitoring trees endangering power lines using a vehicle network, which comprises a plurality of vehicles and a central computer, wherein at least one vehicle of the plurality if vehicles comprises an image capturing sensor system, an image processing unit, and a locating system and is wirelessly connectable to the central computer in a data-conducting manner, and wherein the vehicle network covers a particular area and each vehicle can travel within the area, such that the trees endangering power lines within the area can be automatically monitored by the at least one vehicle during a journey, comprising:
capturing image information of an environment with the image capturing sensor system of the at least one vehicle during a journey;
determining tree information with the image processing unit of the at least one vehicle, taking into account the power lines, based on the captured image information; and
sending from the at least one vehicle to the central computer the determined tree information.

2. The method according to claim 1, wherein:
prior to sending from the at least one vehicle to the central computer the determined tree information, location information regarding the tree information is captured by the locating system; and
sending from the at least one vehicle to the central computer the determined tree information comprises sending the captured location information to the central computer.

3. The method according to claim 1, wherein:
prior to sending from the at least one vehicle to the central computer the determined tree information, the tree information is evaluated by an evaluation unit of the vehicle to detect at least one of the trees endangering power lines, whose branches and leaves may come into contact with at least one of the power lines during growth; and
sending from the at least one vehicle to the central computer the determined tree information comprises sending the tree information with the information of the detected at least one tree to the central computer.

4. The method according to claim 1, further comprising:
evaluating, with the central computer, the tree information to detect at least one of the trees endangering power lines, whose branches and leaves may come into contact with at least one of the power lines during growth.

5. The method according to claim 1, wherein, capturing image information comprises:
capturing image information of an environment using a laser scanner, a camera, and/or a 360° spherical camera.

6. The method according to claim 1, wherein, determining the tree information comprises:
reconstructing 3D image information from the captured image information based on a Structure-from-Motion approach; and
determining the tree information based on the reconstructed 3D image information.

7. A vehicle comprising:
an image capturing sensor system configured to capture image information of an environment of the vehicle during a journey;
an image processing unit configured to determine tree information, taking into account power lines, based on the captured image information; and
a locating system configured to capture location information regarding the tree information, wherein
the vehicle is wirelessly connectable to a central computer in a data-conducting manner in order to send the tree information and the location information regarding the tree information to the central computer.

8. The vehicle according to claim 7, further comprising:
an evaluation unit configured to evaluate the tree information to detect at least one tree endangering at least one power line, whose branches and leaves may come into contact with a power line during growth.

9. A vehicle network for monitoring trees endangering power lines, comprising:
a central computer; and
at least one vehicle including
an image capturing sensor system configured to capture image information of an environment of the at least one vehicle during a journey,
an image processing unit configured to determine tree information, taking into account the power lines, based on the image information,
a locating system configured to capture location information regarding the tree information,
wherein the at least one vehicle is wirelessly connectable to the central computer in a data-conducting manner to send the tree information and the location information regarding the tree information to the central computer.

10. The vehicle network according to claim 9, wherein the at least one vehicle further comprises:
an evaluation unit configured to evaluate the tree information to detect at least one of the trees endangering at least one of the power lines, whose branches and leaves may come into contact with the at least one of the power lines during growth.

11. The vehicle network according to claim 9, wherein the central computer is configured to evaluate the tree information to detect at least one of the trees endangering at least one of the power lines, whose branches and leaves may come into contact with the at least one power line during growth.
